(19) United States
(12) Patent Application Publication
(10) Pub. No.: US 2026/0201556 A1
(43) Pub. Date: Jul. 16, 2026

(54) SUBSTRATE PROCESSING METHOD AND SUBSTRATE PROCESSING APPARATUS

(71) Applicant: Tokyo Electron Limited, Tokyo (JP)

(72) Inventors: Mayuko NAKAMURA, Hsin-chu City (TW); Masahisa WATANABE, Yamanashi (JP); Sakura KOBESSHO, Yamanashi (JP); Yuichiro WAGATSUMA, Hsin-chu City (TW)

(21) Appl. No.: 19/564,776

(22) Filed: Mar. 12, 2026

Related U.S. Application Data
(63) Continuation of application No. PCT/JP2024/031215, filed on Aug. 30, 2024.

(30) Foreign Application Priority Data
Sep. 20, 2023 (JP) 2023-153676

(51) Int. Cl. C23C 16/455; C23C 16/24; C23C 16/52

(52) U.S. Cl. CPC C23C 16/45523; C23C 16/24; C23C 16/52

(57) ABSTRACT

A substrate processing method and a substrate processing apparatus for forming a film containing either or both of silicon and germanium in a recess of a substrate including a base film in which a recess is formed are provided. A substrate processing method for forming a film containing either or both of silicon and germanium in a recess of a substrate including a base film in which the recess is formed, includes: (a) supplying a first film-forming gas containing either or both of silicon and germanium to the substrate; and (b) simultaneously supplying a second film-forming gas containing either or both of silicon and germanium, and a halogen-containing gas to the substrate, wherein the opening width of the recess when starting the (b) after the (a) is 10 nm or less.

### CROSS-REFERENCE TO RELATED APPLICATIONS

This application is a continuation application of International Application No. PCT/JP2024/031215, filed on August 30, 2024, and designating the U.S., which is based upon and claims priority to Japanese Patent Application No. 2023-153676, filed on September 20, 2023, the entire contents of which are incorporated herein by reference.

### BACKGROUND

### TECHNICAL FIELD

The present disclosure relates to a substrate processing method and a substrate processing apparatus.

### BACKGROUND ART

Japanese Patent Application Laid-Open Publication No. 10-321556 discloses a film-forming method for forming a predetermined film on a processing target installed in a processing vessel, which includes a first film-forming step of forming a film on the surface of the processing target by CVD while supplying a film-forming gas into the processing vessel, an etching step of slightly etching the film formed in the first film-forming step while supplying an etching gas into the processing vessel, and a second film-forming step of forming a film on the surface of the processing target by CVD while supplying the same film-forming gas as that used in the first film-forming step into the processing vessel.

### SUMMARY

In order to solve the above problem, according to one aspect, a substrate processing method for forming a film containing either or both of silicon and germanium in a recess of a substrate including a base film in which the recess is formed is provided, wherein the substrate processing method includes: (a) supplying a first film-forming gas containing either or both of silicon and germanium to the substrate; and (b) simultaneously supplying a second film-forming gas containing either or both of silicon and germanium and a halogen-containing gas to the substrate, wherein an opening width of the recess when starting the (b) after the (a) is 10 nm or less.

### BRIEF DESCRIPTION OF THE DRAWINGS

FIG. 1 is an example of a schematic diagram showing a configuration example of a substrate processing apparatus;

FIG. 2 is a flowchart showing an example of a substrate processing method according to a first embodiment;

FIG. 3A is a schematic diagram showing an example of a state of a substrate surface in each step of the substrate processing method according to the first embodiment;

FIG. 3B is a schematic diagram showing an example of a state of a substrate surface in each step of the substrate processing method according to the first embodiment;

FIG. 3C is a schematic diagram showing an example of a state of a substrate surface in each step of the substrate processing method according to the first embodiment;

FIG. 4 is a flowchart showing an example of a substrate processing method according to a second embodiment;

FIG. 5 is a flowchart showing an example of a substrate processing method according to a third embodiment;

FIG. 6A is a schematic diagram showing an example of a state of a substrate surface in each step of a substrate processing method according to a third embodiment;

FIG. 6B is a schematic diagram showing an example of a state of a substrate surface in each step of the substrate processing method according to the third embodiment;

FIG. 6C is a schematic diagram showing an example of a state of a substrate surface in each step of the substrate processing method according to the third embodiment;

FIG. 6D is a schematic diagram showing an example of a state of a substrate surface in each step of the substrate processing method according to the third embodiment;

FIG. 6E is a schematic diagram showing an example of a state of a substrate surface in each step of the substrate processing method according to the third embodiment;

FIG. 6F is a schematic diagram showing an example of a state of a substrate surface in each step of the substrate processing method according to the third embodiment;

FIG. 6G is a schematic diagram showing an example of a state of a substrate surface in each step of the substrate processing method according to the third embodiment; and

FIG. 6H is a schematic diagram showing an example of a state of a substrate surface in each step of the substrate processing method according to the third embodiment.

### DETAILED DESCRIPTION OF THE INVENTION

Hereinafter, an embodiment for carrying out the present disclosure will be described with reference to the drawings. In the drawings, the same components are denoted by the same reference numerals, and redundant descriptions may be omitted.

### Substrate Processing Apparatus

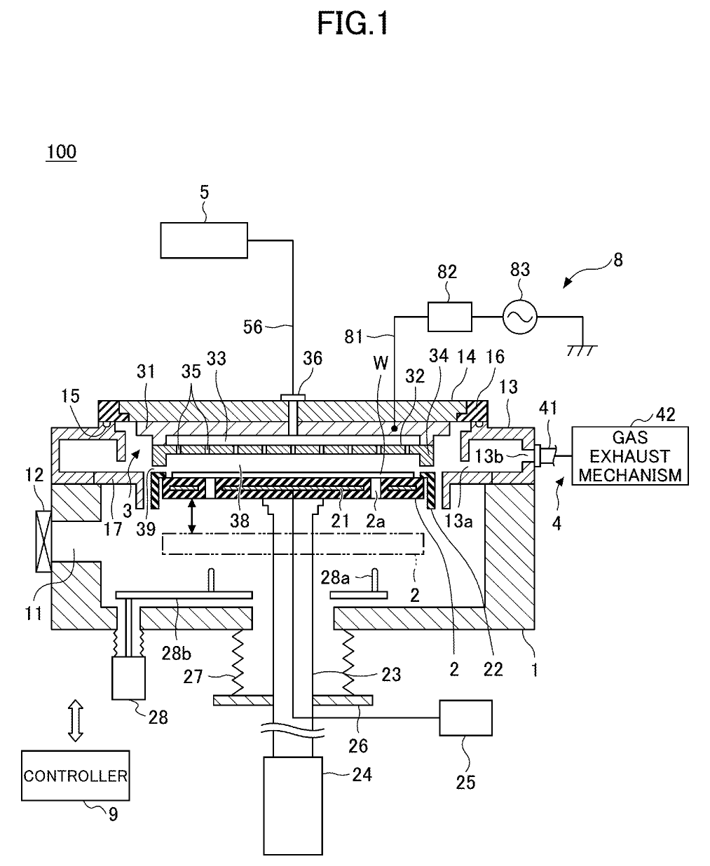

A substrate processing apparatus 100 according to the present embodiment will be described with reference to FIG. 1. FIG. 1 is an example of a schematic diagram showing a configuration example of the substrate processing apparatus 100.

As shown in FIG. 1, the substrate processing apparatus 100 includes a processing vessel 1, a mounting table 2, a showerhead 3, a gas exhaust 4, a gas supply mechanism 5, an RF power supply 8, and a controller 9.

The processing vessel 1 is composed of a metal, such as aluminum and the like, and has a substantially cylindrical shape. The processing vessel 1 houses a substrate W. A loading/unloading port 11 for loading or unloading a substrate W is formed in a side wall of the processing vessel 1, and the loading/unloading port 11 is opened and closed by a gate valve 12. An annular gas exhaust duct 13 having a rectangular cross-sectional shape is provided on the main body of the processing vessel 1. The gas exhaust duct 13 is provided with a slit 13a along an inner peripheral surface of the gas exhaust duct 13. A gas exhaust port 13b is formed in an outer wall of the gas exhaust duct 13. A top wall 14 is provided on an upper surface of the gas exhaust duct 13 to close an upper opening of the processing vessel 1 via an insulator member 16. The gap between the gas exhaust duct 13 and the insulator member 16 is airtightly sealed by a seal ring 15. A partitioning member 17 partitions the interior of the processing vessel 1 into an upper and lower sections when the mounting table 2 (and a cover member 22) is raised to a processing position described later.

The mounting table (substrate support) 2 horizontally supports the substrate W in the processing vessel 1. The mounting table 2 is formed in a disk shape having a size corresponding to the substrate W, and is supported by a support member 23. The mounting table 2 is composed of a ceramic material, such as AlN and the like, or a metal material, such as aluminum, a nickel alloy, and the like, and a heater 21 for heating the substrate W is embedded in the mounting table 2. The heater 21 is supplied with power from a heater power source 25 and generates heat. Then, by controlling an output from the heater 21 in accordance with a temperature signal from a thermocouple (not shown) provided near the upper surface of the mounting table 2, the substrate W is controlled to a predetermined temperature. The mounting table 2 is provided with the cover member 22 composed of a ceramic material, such as alumina and the like, to cover the outer peripheral region of the upper surface of the mounting table 2 and the side surface of the mounting table 2.

A support member 23 for supporting the mounting table 2 is provided on the bottom surface of the mounting table 2. The support member 23 extends from the center of the bottom surface of the mounting table 2 to under the processing vessel 1 through a hole formed in the bottom wall of the processing vessel 1, and the lower end of the support member 23 is connected to a lifting mechanism 24. The lifting mechanism 24 raises and lowers the mounting table 2 via the support member 23 between the processing position shown in FIG. 1 and a conveying position at which the substrate W can be conveyed, shown by a two-dot chain line under the processing position. The support member 23 is provided with a flange 26 under the bottom surface of the processing vessel 1. A bellows 27 is provided between the bottom surface of the processing vessel 1 and the flange 26 to partition the atmosphere in the processing vessel 1 from the open air and to extend and contract in accordance with the lifting operation of the mounting table 2.

Near the bottom surface of the processing vessel 1, three wafer supporting pins 28a (only two are shown) are provided to project upward from a lifting plate 28b. The wafer supporting pins 28a are raised and lowered via the lifting plate 28b by a lifting mechanism 28 provided under the processing vessel 1. The wafer supporting pins 28a are inserted through through-holes 2a provided in the mounting table 2 that is at the conveying position, and can be projected from and retracted into upper surface of the mounting table 2. By raising and lowering the wafer supporting pins 28a, the substrate W is passed between a conveying mechanism (not shown) and the mounting table 2.

A showerhead 3 supplies a processing gas into the processing vessel 1 in the form of a shower. The showerhead 3 is composed of a metal, is provided to face the mounting table 2, and has a diameter substantially equal to that of the mounting table 2. The showerhead 3 includes a body part 31 fixed to the top wall 14 of the processing vessel 1 and a shower plate 32 connected under the body part 31. A gas diffusion space 33 is formed between the body part 31 and the shower plate 32, and the gas diffusion space 33 is provided with a gas introduction hole 36 to penetrate the center of the top wall 14 of the processing vessel 1 and the body part 31. An annular projection 34 projecting downward is formed on the periphery of the shower plate 32. Gas discharge holes 35 are formed in a flat surface within the annular projection 34. When the mounting table 2 is present at the processing position, a processing space 38 is formed between the mounting table 2 and the shower plate 32, and the upper surface of the cover member 22 and the annular projection 34 are close to each other to form an annular gap 39.

The gas exhaust 4 exhausts any gas from the interior of the processing vessel 1. The gas exhaust 4 includes a gas exhaust pipe 41 connected to the gas exhaust port 13b, and a gas exhaust mechanism 42 connected to the gas exhaust pipe 41 and including a vacuum pump, a pressure control valve, and the like. During processing, any gas in the processing vessel 1 reaches the gas exhaust duct 13 via the slit 13a, and is exhausted by the gas exhaust mechanism 42 from the gas exhaust duct 13 through the gas exhaust pipe 41.

A gas supply mechanism (gas supply) 5 supplies a processing gas into the processing vessel 1. The gas supply mechanism 5 is connected to the gas introduction hole 36 through a gas supply line 56.

The substrate processing apparatus 100 is a capacitively coupled plasma apparatus in which the mounting table 2 serves as a lower electrode and the showerhead 3 serves as an upper electrode. The mounting table 2 serving as the lower electrode is grounded via a capacitor (not shown).

A high-frequency power (hereinafter also referred to as “RF power”) is applied to the showerhead 3 serving as the upper electrode from the RF power supply 8. The RF power supply 8 includes a power supply line 81, a matcher 82, and an RF power source 83. The RF power source 83 is a power source for generating an RF power. The RF power has a frequency suitable for forming a plasma. The frequency of the RF power is, for example, a frequency within a range of 450 KHz to 100 MHz. The RF power source 83 is connected to the body part 31 of the showerhead 3 via the matcher 82 and the power supply line 81. The matcher 82 includes a circuit for matching the output reactance of the RF power source 83 with the reactance of the load (upper electrode). Although the RF power supply 8 has been described as applying an RF power to the showerhead 3 serving as the upper electrode, this is non-limiting. The RF power supply 8 may be configured to apply an RF power to the mounting table 2 serving as the lower electrode. The substrate processing apparatus 100 does not need to include a component for applying an RF power.

The controller 9 is, for example, a computer, and includes a Central Processing Unit (CPU), a Random Access Memory (RAM), a Read Only Memory (ROM), an auxiliary memory, and the like. The CPU operates based on a program stored in the ROM or the auxiliary memory, and controls the operation of the substrate processing apparatus 100. The controller 9 may be provided inside or outside the substrate processing apparatus 100. When the controller 9 is provided outside the substrate processing apparatus 100, the controller 9 can control the substrate processing apparatus 100 by wired, wireless, and other communication methods.

Although the substrate processing apparatus 100 has been described as a single-wafer type substrate processing apparatus 100 as shown in FIG. 1, this is non-limiting. The substrate processing apparatus may be a batch-type substrate processing apparatus that processes a large number of substrates W by mounting them on multiple stages, or a semi-batch-type substrate processing apparatus.

### Substrate Processing Method According to First Embodiment

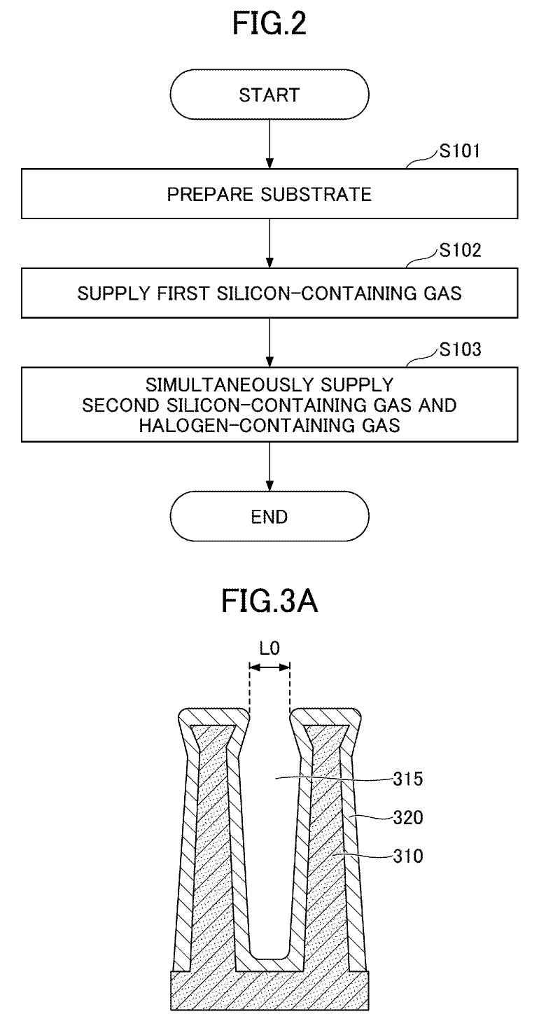

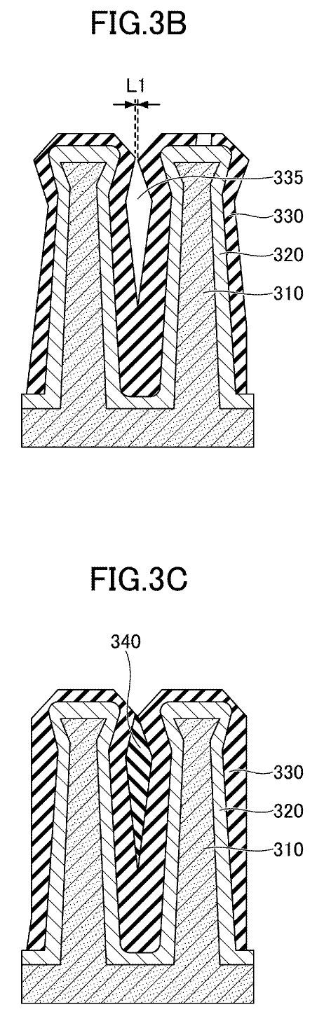

Next, a substrate processing method according to a first embodiment using the substrate processing apparatus 100 will be described with reference to FIGS. 2 and 3A to 3C. FIG. 2 is a flowchart showing an example of the substrate processing method according to the first embodiment. FIGS. 3A to 3C are schematic views showing an example of a state of a substrate surface in each step of the substrate processing method according to the first embodiment. Here, a case of forming silicon-containing films (a first silicon-containing film 330 and a second silicon-containing film 340) in a recess 315 (see FIG. 3A) of a substrate W in which the recess 315 is formed will be described.

In step S101, a substrate W is prepared. Here, the controller 9 opens the gate valve 12. The substrate W is conveyed into the processing vessel 1 from the loading/unloading port 11 by a conveying device (not shown), and is mounted on the mounting table 2. When the conveying device retreats from the loading/unloading port 11, the controller 9 closes the gate valve 12. Next, the controller 9 controls the gas exhaust mechanism 42 to exhaust any air from the interior of the processing vessel 1. Next, the controller 9 controls the lifting mechanism 24 to raise the mounting table 2 from the conveying position to the processing position. Further, the controller 9 may control the heater power source 25 to cause the heater 21 to generate heat to preheat the substrate W mounted on the mounting table 2.

FIG. 3A is a schematic diagram showing an example of the state of the substrate surface of the substrate W prepared in step S101. The substrate W includes a first film 310 and a second film (base film) 320. The first film 310 is an insulator film (dielectric film) composed of, for example, SiN, but is not limited to this. Further, the first film 310 includes a recess 315, such as a trench, a hole, and the like. The second film 320 is an insulator film (dielectric film) composed of, for example, a silicon oxide film (SiO₂). The second film 320 is formed to cover the entirety of the surface of the first film 310 including the recess 315. In other words, the substrate surface of the substrate W prepared in step S101 is composed of the second film (base film) 320 composed of a silicon oxide film (for example, SiO₂), and includes the recess 315, such as a trench, a hole, and the like.

In step S102, a first silicon-containing gas (a first film-forming gas) is supplied to the substrate W. Here, the controller 9 controls the gas supply mechanism 5 to supply the first silicon-containing gas into the processing space 38. The controller 9 may be configured to control the RF power supply 8 to form a plasma in the processing space 38. Thus, the first silicon-containing film 330 (see FIG. 3B) is formed on the substrate surface of the substrate W by Chemical Vapor Deposition (CVD) or Plasma-Enhanced CVD. In other words, the first silicon-containing film 330 is formed on the surface of the second film (base film) 320.

The first silicon-containing gas may be, for example, a gas of any of monosilane (SiH₄), disilane (Si₂H₆), trisilane (Si₃H₈), tetrasilane (Si₄H₁₀), dichlorosilane (SiH₂Cl₂), or the like, or a mixed gas thereof. The first silicon-containing film 330 formed in step S102 is, for example, an amorphous silicon film.

FIG. 3B is a schematic diagram showing an example of the state of the substrate surface of the substrate W on which the first silicon-containing film 330 is formed in step S102. Here, the first silicon-containing film 330 is formed on the second film (base film) 320 of the substrate W. That is, the first silicon-containing film 330 is also formed on the upper part of the trench and on the side wall and bottom of the recess 315 with a good coverage. As a result, the opening width L1 of the recess 335 (see FIG. 3B) after the first silicon-containing film 330 is formed becomes narrower than the opening width L0 of the recess 315 (see FIG. 3A) before the first silicon-containing film 330 is formed. That is, step S102 is a step of supplying the first silicon-containing gas to the substrate W to form the first silicon-containing film 330 on the substrate surface of the substrate W, thereby narrowing the opening width of the recess formed in the substrate surface of the substrate W.

In the step S103, a second silicon-containing gas (a second film-forming gas) and a halogen-containing gas (an etching gas) are simultaneously supplied to the substrate W. Here, the controller 9 controls the gas supply mechanism 5 to supply the second silicon-containing gas and the halogen-containing gas into the processing space 38. Thus, a second silicon-containing film 340 (see FIG. 3C) is formed on the substrate surface of the substrate W by CVD. In other words, the second silicon-containing film 340 is formed on the substrate surface of the first silicon-containing film 330.

The second silicon-containing gas may be, for example, a gas of any of monosilane (SiH₄), disilane (Si₂H₆), trisilane (Si₃H₈), tetrasilane (Si₄H₁₀), dichlorosilane (SiH₂Cl₂), or the like, or a mixed gas thereof. The halogen-containing gas may be, for example, any of chlorine gas (Cl₂), hydrogen bromide gas (HBr), fluorine gas (F₂), hydrogen iodide gas (HI), or the like. The first silicon-containing gas and the second silicon-containing gas may be the same gas or may be different gases, and are not limited. The second silicon-containing film 340 formed in step S103 is, for example, an amorphous silicon film.

FIG. 3C is a schematic diagram showing an example of the state of the substrate surface of the substrate W on which the second silicon-containing film 340 is formed in step S103. Here, the second silicon-containing film 340 is selectively embedded in the recess 335 (see FIG. 3B of which the opening width has been narrowed.

Here, the opening width L1 of the recess 335 when starting step S103 after the step S102 is preferably 10 nm or less. This makes it difficult for the halogen-containing gas to reach inside the recess 335. On the other hand, the second silicon-containing gas can sufficiently reach inside the recess 335. Therefore, in the recess 335 having the opening width L1 of 10 nm or less, the film-forming rate by the second silicon-containing gas exceeds the film-forming inhibiting rate by the halogen-containing gas, and the second silicon-containing film 340 is selectively formed. On the other hand, on the top of the side wall of the recess 335, formation of the second silicon-containing film 340 is inhibited by the halogen-containing gas. Thus, the second silicon-containing film 340 can be embedded in the recess 335 in a void-less and seamless manner. In a recess having an opening width greater than 10 nm, the second silicon-containing gas and the halogen-containing gas can easily reach inside the concave 335 like they can reach the top of the side wall of the recess 335 (the top the trench), thereby formation of the second silicon-containing film 340 in the recess 335 is inhibited as well. Therefore, it is difficult to form the second silicon-containing film 340 in the recess 335.

In step S103, the film-forming rate at the top of the side wall of the recess 335 (the top of the trench) is preferably approximately 0 nm/min (specifically, within a range of -0.1 nm/min to +1.1 nm/min). In other words, in the step S103, it is preferable to control the flow rate of the second silicon-containing gas, the flow rate of the halogen-containing gas, the pressure in the processing vessel 1, the temperature of the substrate W, and the like such that the film-forming rate at the top of the side wall of the recess 335 is approximately 0 nm/min (specifically, within a range of -0.1 nm/min to +1.1 nm/min). Thus, formation of the second silicon-containing film 340 on the top of the side wall of the recess 335 is inhibited. On the other hand, the second silicon-containing film 340 is embedded in the recess 335. If the film-forming rate on the top of the side wall of the recess 335 (the top of the trench) is higher than the above range, there is a risk that the opening of the recess 335 is closed before the second silicon-containing film 340 is embedded in the recess 335, to form a void or the like. If the film-forming on the top of the side wall of the recess 335 (the top of the trench) is lower than the above range, there is a risk that formation of the second silicon-containing film 340 is inhibited in the recess 335 as well.

As described above, according to the substrate processing method according to the first embodiment, the silicon-containing films (the first silicon-containing film 330 and the second silicon-containing film 340) can be embedded in the recess 315 in a void-less and seamless manner.

In addition, according to the substrate processing method according to the first embodiment, when embedding the silicon-containing film in the recess 315, it can be performed through two film-forming steps (S102 and S103). Thus, the embedding controllability is improved as compared with a substrate processing method of embedding a silicon-containing film in the recess by repeating a film-forming step and an etching step. Furthermore, the in-plane embedding uniformity on the substrate and the embedding uniformity between substrates can be improved. In addition, according to the substrate processing method according to the first embodiment, the processing time can be shortened as compared with the substrate processing method of embedding a silicon-containing film in the recess by repeating a film-forming step and an etching step. Thus, the processing capability of the substrate processing apparatus 100 is improved. In addition, according to the substrate processing method according to the first embodiment, no step of purging any gas in the processing vessel 1 needs to be performed between the step of forming the first silicon-containing film 330 (S102) and the step of forming the second silicon-containing film 340 (S103). Thus, the processing time can be shortened.

In addition, according to the substrate processing method according to the first embodiment, compared with the substrate processing method of embedding a silicon-containing film in the recess by repeating a film-forming step and an etching step, it is possible to prevent the top of the sidewall of the recess 315 of the second film (base film) 320 from being exposed in an etching step. Thus, it is possible to inhibit formation of microcrystals in the amorphous silicon film. In addition, it is possible to inhibit damage to the second film (base film) 320 that might be caused by the halogen-containing gas (etching gas).

### Substrate Processing Method According to Second Embodiment

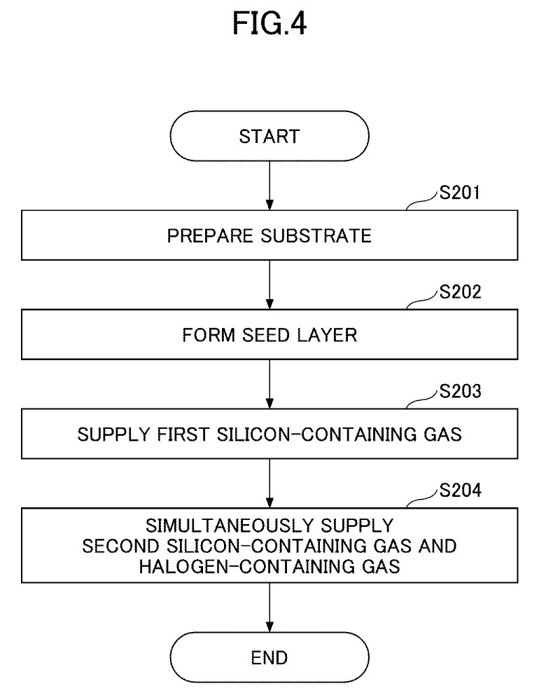

Next, a substrate processing method according to a second embodiment using the substrate processing apparatus 100 will be described with reference to FIG. 4. FIG. 4 is a flowchart showing an example of the substrate processing method according to the second embodiment.

In step S201, a substrate W is prepared as in step S101.

In step S202, a seed gas containing silicon is supplied to the substrate W to form a seed layer (not shown) on the surface of the substrate W. Here, for example, a high-order silane, such as aminosilane, disilane, and/or the like can be used as the seed gas.

In step S203, as in step S102, a first silicon-containing gas (a first film-forming gas) is supplied to the substrate W to form a first silicon-containing film 330 on the seed layer (not shown), thereby narrowing the opening width of the recess formed in the substrate surface of the substrate W.

In step S204, as in step S103, a second silicon-containing gas (a second film-forming gas) and a halogen-containing gas (an etching gas) are supplied to the substrate W to embed a second silicon-containing film 340 in the recess 335 in a void-less and seamless manner.

As described above, according to the substrate processing method according to the second embodiment, the silicon-containing films (the first silicon-containing film 330 and the second silicon-containing film 340) can be embedded in the recess in a void-less and seamless manner.

Further, by forming the seed layer, the flatness of the amorphous silicon films (the first silicon-containing film 330 and the second silicon-containing film 340) is improved. Further, by forming the amorphous silicon films (the first silicon-containing film 330 and the second silicon-containing film 340) by starting from the seed layer, the incubation time (film formation start delay time) is shortened.

### Substrate Processing Method According to Third Embodiment

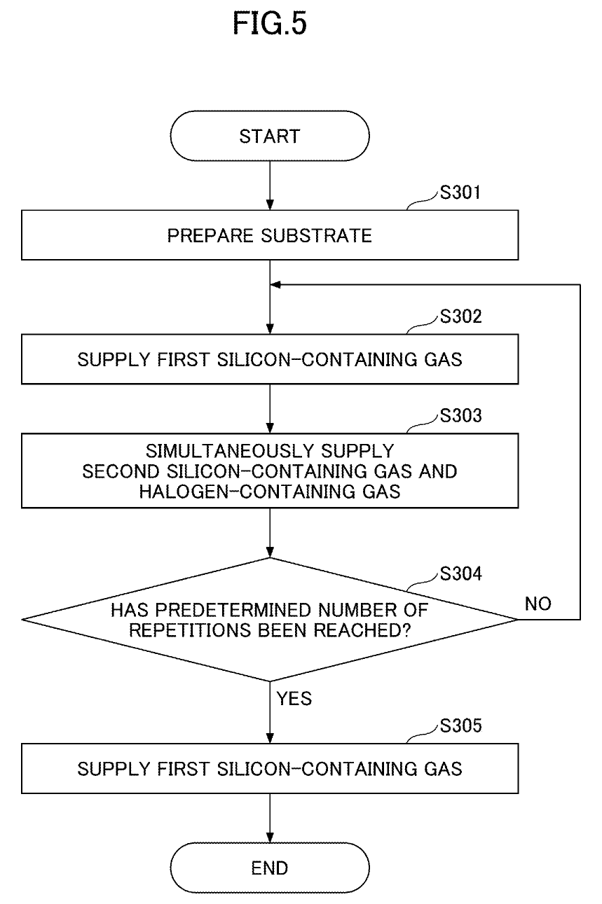

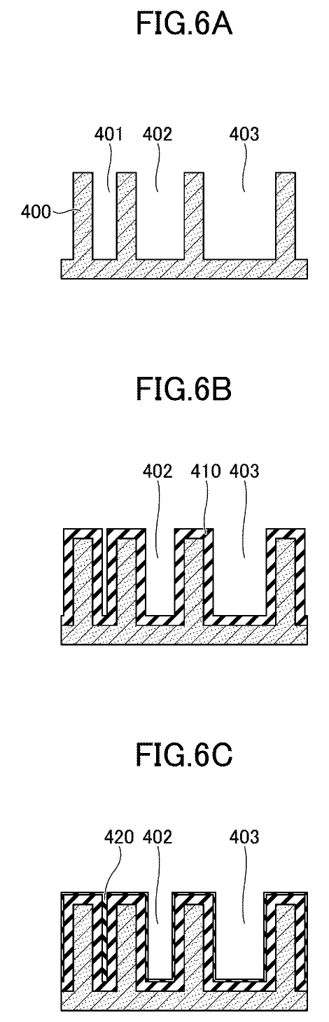

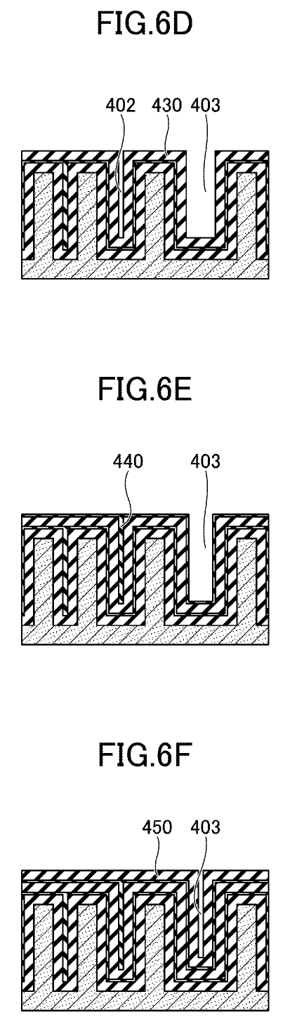

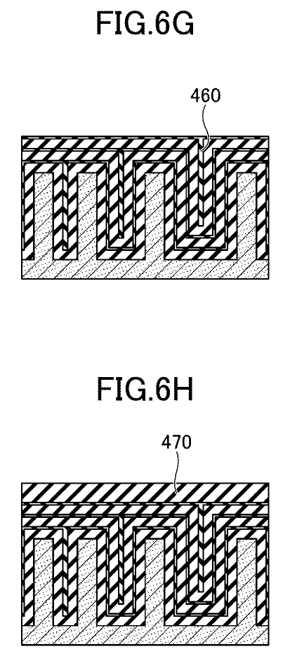

Next, a substrate processing method according to a third embodiment using the substrate processing apparatus 100 will be described with reference to FIG. 5 and FIGS. 6A to 6H. FIG. 5 is a flowchart showing an example of the substrate processing method according to the third embodiment. FIGS. 6A to 6H are schematic diagrams showing an example of the state of the substrate surface in each step of the substrate processing method according to the third embodiment. Here, a case of forming silicon-containing films in a plurality of recesses 401, 402, and 403 of a substrate W including a base film 400 in which the plurality of recesses 401, 402, and 403 having different opening widths are formed will be described.

In step S301, a substrate W is prepared as in step S101. FIG. 6A is a schematic diagram showing an example of the state of the substrate surface of the substrate W prepared in step S301. The substrate W includes a base film 400 in which a plurality of recesses 401, 402, and 403 having different opening widths are formed. In the following description, the opening widths are ordered from narrowest to widest as follows: the recess 401, the recess 402, and the recess 403. The base film 400 is an insulator film (dielectric film) composed of a silicon oxide film (SiO₂).

In step S302, as in step S102, a first silicon-containing gas (a first film-forming gas) is supplied to the substrate W. FIG. 6B is a schematic diagram showing an example of the state of the substrate surface of the substrate W on which a first silicon-containing film 410 is formed in step S302. Thus, the first silicon-containing film 410 is formed on the substrate surface of the substrate W by CVD or plasma CVD. Further, the opening width of the recess 401 formed in the substrate surface of the substrate W is narrowed to equal to or less than a predetermined opening width (for example, 10 nm or less).

In step S303, as in step S103, a second silicon-containing gas (a second film-forming gas) and a halogen-containing gas (an etching gas) are supplied to the substrate W. FIG. 6C is a schematic diagram showing an example of the state of the substrate surface of the substrate W on which a second silicon-containing film 420 is formed in step S303. The halogen-containing gas can hardly reach the recess 401 having equal to or less than the predetermined opening width (for example, 10 nm or less), whereas the second silicon-containing gas can reach the recess and embed the second silicon-containing film 420 in the recess in a void-less and seamless manner. Meanwhile, the second silicon-containing gas and the halogen-containing gas reach the top of the side wall of the recess 401 and the recesses 402 and 403, thereby inhibiting formation of the second silicon-containing film 420.

In step S304, the controller 9 determines whether or not a predetermined number of repetitions has been reached. When the predetermined number of repetitions has not been reached (NO in S304), the processing by the controller 9 returns to step S302.

In step S302 for the second time, the first silicon-containing gas (the first film-forming gas) is supplied to the substrate W. FIG. 6D is a schematic diagram showing an example of the state of the substrate surface of the substrate W on which a third silicon-containing film 430 is formed in step S302. Thus, the third silicon-containing film 430 is formed on the substrate surface of the substrate W by CVD or plasma CVD. Further, the opening width of the recess 402 formed in the substrate surface of the substrate W is narrowed to equal to or less than a predetermined opening width (for example, 10 nm or less).

In step S303 for the second time, the second silicon-containing gas (the second film-forming gas) and the halogen-containing gas (the etching gas) are supplied to the substrate W. FIG. 6E is a schematic diagram showing an example of the state of the substrate surface of the substrate W on which a fourth silicon-containing film 440 is formed in the step S303. The halogen-containing gas can hardly reach the recess 402 having equal to or less than the predetermined opening width (for example, 10 nm or less), whereas the second silicon-containing gas can reach the recess and embed the fourth silicon-containing film 440 in the recess in a void-less and seamless manner. Meanwhile, the second silicon-containing gas and the halogen-containing gas reach the top of the side wall of the recess 402 and the recess 403, thereby inhibiting formation of the fourth silicon-containing film 440.

In step S304, the controller 9 determines whether or not the predetermined number of repetitions has been reached. When the predetermined number of repetitions has not been reached (NO in step S304), the processing by the controller 9 returns to step S302.

In step S302 for the third time, the first silicon-containing gas (the first film-forming gas) is supplied to the substrate W. FIG. 6F is a schematic diagram showing an example of the state of the substrate surface of the substrate W on which a fifth silicon-containing film 450 is formed in the step S302. Thus, the fifth silicon-containing film 450 is formed on the substrate surface of the substrate W by CVD or plasma CVD. In addition, the opening width of the recess 403 formed in the substrate surface of the substrate W is narrowed to equal to or less than a predetermined opening width (for example, 10 nm or less).

In the third step S303, the second silicon-containing gas (the second film-forming gas) and the halogen-containing gas (the etching gas) are supplied to the substrate W. FIG. 6G is a schematic diagram showing an example of the state of the substrate surface of the substrate W on which a sixth silicon-containing film 460 is formed in the step S303. The halogen-containing gas can hardly reach the recess 403 equal to or less than the predetermined opening width (for example, 10 nm or less), whereas the second silicon-containing gas can reach the recess and embed the sixth silicon-containing film 460 in the recess in a void-less and seamless manner. Meanwhile, the second silicon-containing gas and the halogen-containing gas reach the top of the side wall of the recess 403, thereby inhibiting formation of the sixth silicon-containing film 460.

In step S304, the controller 9 determines whether or not the predetermined number of repetitions has been reached. When the predetermined number of repetitions has been reached (YES in step S304), the processing by the controller 9 proceeds to step S305.

In step S305, the first silicon-containing gas (the first film-forming gas) is supplied to the substrate W. FIG. 6H is a schematic diagram showing an example of the state of the substrate surface of the substrate W on which a seventh silicon-containing film 470 is formed in step S305. Thus, the seventh silicon-containing film 470 (see FIG. 6H) is formed on the substrate surface of the substrate W by CVD or plasma CVD.

As described above, according to the substrate processing method according to the third embodiment, one cycle composed of the process of step S302 and the process of step S303 is repeated (see step S304) for the recesses 401, 402, and 403 having different opening widths, to embed silicon-containing films in the recesses 401, 402, and 403 in this narrower opening width order. According to the substrate processing method according to the third embodiment, the silicon-containing films can be embedded in a void-less and seamless manner as in the substrate processing method according to the first embodiment.

In the substrate processing method of repeating a film-forming step and an etching step to embed silicon-containing films in the recesses, it is necessary to adjust the film-forming condition in the film-forming step and the etching condition in the etching step for each opening width, and the difficulty with embedding the silicon-containing film in a void-less and seamless manner is high. On the other hand, according to the substrate processing method according to the third embodiment, it is possible to embed the silicon-containing film in a void-less and seamless manner only by adjusting the film-forming time in the step S302, of the steps S302 and S303, for each opening width (the film-forming condition in the step S303 is fixed). Note that the film-forming condition in the step S303 does not need to be fixed.

The substrate processing method according to the present embodiment (first to third embodiments) has been described based on an example case of forming a silicon-containing film in a recess of the substrate W. However, this is non-limiting. The substrate processing method according to the present embodiments (the first to third embodiments) may also be applied to a case of forming a film containing either or both of silicon and germanium in a recess of the substrate W. That is, a gas containing a first silicon and/or germanium may be used as the first film-forming gas, and a gas containing a second silicon and/or germanium may be used as the second film-forming gas. As the first film-forming gas containing germanium, a gas of any of germane (GeH₄), digermane (Ge₂H₆), or germanium tetrachloride (GeCl₄) may be used. As the second film-forming gas containing germanium, a gas of any of germane (GeH₄), digermane (Ge₂H₆), or germanium tetrachloride (GeCl₄) may be used. The first film-forming gas and the second film-forming gas may be the same gas. The halogen-containing gas supplied simultaneously with the second film-forming gas containing germanium may be any of chlorine gas (Cl₂), hydrogen bromide gas (HBr), fluorine gas (F₂), or hydrogen iodide gas (HI). Further, the present disclosure may be applied to a case of forming a silicon and/or germanium-containing film doped with an impurity, such as B (boron), P (phosphorus), C (carbon), or the like.

Although the substrate processing method according to the present embodiments (the first to third embodiments) using the substrate processing apparatus 100 has been described above, the present disclosure is not limited to the above embodiments and the like, and various modifications and improvements are applicable within the scope of the spirit of the present disclosure described in the claims.

According to one aspect, it is possible to provide a substrate processing method and a substrate processing apparatus for forming a film containing either or both of silicon and germanium in a recess of a substrate including a base film in which the recess is formed.

What is claimed is:

1. A substrate processing method for forming a film containing either or both of silicon and germanium in a recess of a substrate including a base film in which the recess is formed, the substrate processing method comprising:
(a) supplying a first film-forming gas containing either or both of silicon and germanium to the substrate; and
(b) supplying a second film-forming gas containing either or both of silicon and germanium, and a halogen-containing gas simultaneously to the substrate,
wherein an opening width of the recess when starting the (b) after the (a) is 10 nm or less.

2. The substrate processing method according to claim 1,
wherein in the (b), a film-forming rate at a top of a sidewall of the recess is within a range of -0.1 nm/min to +1.1 nm/min.

3. The substrate processing method according to claim 2,
wherein in the (a), a film containing either or both of a first silicon and germanium is formed to narrow the opening width of the recess, and
in the (b), a film containing either or both of a second silicon and germanium is embedded in the recess.

4. The substrate processing method according to claim 1,
wherein the base film includes a plurality of recesses, each of which is the recess, the plurality of recesses having different opening widths.

5. The substrate processing method according to claim 4,
wherein one cycle composed of the (a) and the (b) is repeated, to embed the film containing either or both of silicon and germanium in the plurality of recesses in order from those of the plurality of recesses having narrower opening widths.

6. The substrate processing method according to claim 1,
wherein the base film is a silicon oxide film.

7. The substrate processing method according to claim 1,
wherein the first film-forming gas is a gas of any of SiH₄ Si₂H₆ Si₃H₈ Si₄H₁₀ or SiH₂Cl₂ or a mixed gas of SiH₄ Si₂H₆ Si₃H₈ Si₄H₁₀ and SiH₂Cl₂
the second film-forming gas is a gas of any of SiH₄ Si₂H₆ Si₃H₈ Si₄H₁₀ or SiH₂Cl₂ or a mixed gas of SiH₄ Si₂H₆ Si₃H₈ Si₄H₁₀ and SiH₂Cl₂ and
the halogen-containing gas is a gas of Cl₂ HBr, F₂ or HI.

8. The substrate processing method according to claim 7,
wherein the first film-forming gas and the second film-forming gas are identical.

9. A substrate processing apparatus, comprising:
a processing vessel;
a substrate support configured to support a substrate in the processing vessel;
a gas supply configured to supply a gas into the processing vessel; and
a controller including a processor and a memory,
wherein the controller is configured to perform:
(a) supplying a first film-forming gas containing either or both of silicon and germanium to a substrate including a base film in which a recess is formed;
(b) simultaneously supplying a second film-forming gas containing either or both of silicon and germanium, and a halogen-containing gas to the substrate, and
wherein an opening width of the recess when starting the (b) after the (a) is 10 nm or less.
